(19) United States
(12) Patent Application Publication
(10) Pub. No.: US 2023/0205068 A1
(43) Pub. Date: Jun. 29, 2023

(54) LIGHT-EMITTING DEVICE, PROJECTOR, AND DISPLAY

(71) Applicants: SOPHIA SCHOOL CORPORATION, TOKYO (JP); SEIKO EPSON CORPORATION, TOKYO (JP)

(72) Inventors: Koichiro AKASAKA, NAGANO-KEN INA-SHI (JP); Koichi MOROZUMI, NAGANO-KEN SHIOJIRI-SHI (JP); Shunsuke ISHIZAWA, TOKYO TO SHINJUKU KU (JP); Katsumi KISHINO, TOKYO TO AKIRUNO-SHI (JP)

(73) Assignees: SOPHIA SCHOOL CORPORATION, TOKYO (JP); SEIKO EPSON CORPORATION, Tokyo (JP)

(21) Appl. No.: 18/086,671

(22) Filed: Dec. 22, 2022

(30) Foreign Application Priority Data
Dec. 23, 2021 (JP) 2021-209201

(51) Int. Cl. G03B 21/20; H01S 5/343

(52) U.S. Cl. CPC G03B 21/2033; H01S 5/34333; H01S 5/34346

(57) ABSTRACT

A light-emitting device that includes a substrate, and at least one column portion, wherein the column portion includes a first semiconductor layer of a first conductivity type, a second semiconductor layer of a second conductivity type different from the first conductivity type, and a light-emitting layer provided between the first semiconductor layer and the second semiconductor layer, the first semiconductor layer is provided between the substrate and the light-emitting layer, the light-emitting layer includes a first well layer, and a barrier layer, the barrier layer includes a first layer provided between the first semiconductor layer and the first well layer, and the first layer has a cubic crystal structure.

The present application is based on, and claims priority from JP Application Serial Number 2021-209201, filed Dec. 23, 2021, the disclosure of which is hereby incorporated by reference herein in its entirety.

### BACKGROUND

### 1. Technical Field

The present disclosure relates to a light-emitting device, a projector, and a display.

### 2. Related Art

Semiconductor lasers are expected as high-brightness next generation light sources. In particular, a semiconductor laser with a nano-column applied is expected to be able to realize high power light emission at a narrow emission angle due to an effect of a photonic crystal by the nano-column.

For example, JP 2020-57640 A describes a light-emitting device provided with a plurality of column portions each including a light-emitting layer that is an i-type InGaN layer, and a barrier layer that is an i-type GaN layer.

In the light-emitting device including the InGaN layer as described above, when the InGaN layer is grown, In is selectively taken into a center of the column portion. Therefore, when a current is injected into the column portion, the current flows between the InGaN layer and a side surface of the column portion, and luminous efficiency may be reduced.

### SUMMARY

An aspect of a light-emitting device according to the present disclosure includes

a substrate, and

at least one column portion, wherein

the column portion includes

a first semiconductor layer of a first conductivity type,

a second semiconductor layer of a second conductivity type different from the first conductivity type, and

a light-emitting layer provided between the first semiconductor layer and the second semiconductor layer,

the first semiconductor layer is provided between the substrate and the light-emitting layer,

the light-emitting layer includes a first well layer, and a barrier layer,

the barrier layer includes a first layer provided between the first semiconductor layer and the first well layer, and

the first layer has a cubic crystal structure.

An aspect of a projector according to the present disclosure includes an aspect of the light-emitting device.

An aspect of a display according to the present disclosure includes an aspect of the light-emitting device.

### BRIEF DESCRIPTION OF THE DRAWINGS

FIG. 1 is a cross-sectional view schematically illustrating a light-emitting device according to the present exemplary embodiment.

FIG. 2 is a plan view schematically illustrating the light-emitting device according to the present exemplary embodiment.

FIG. 3 is a cross-sectional view schematically illustrating the light-emitting device according to the present exemplary embodiment.

FIG. 4 is a cross-sectional view schematically illustrating a manufacturing process of the light-emitting device according to the present exemplary embodiment.

FIG. 5 is a cross-sectional view schematically illustrating a manufacturing process of the light-emitting device according to the present exemplary embodiment.

FIG. 6 is a cross-sectional view schematically illustrating a manufacturing process of the light-emitting device according to the present exemplary embodiment.

FIG. 7 is a cross-sectional view schematically illustrating a manufacturing process of the light-emitting device according to the present exemplary embodiment.

FIG. 8 is a diagram schematically illustrating a projector according to the present exemplary embodiment.

FIG. 9 is a plan view schematically illustrating a display according to the present exemplary embodiment.

FIG. 10 is a cross-sectional view schematically illustrating the display according to the present exemplary embodiment.

FIG. 11 is a TEM image of a column portion.

FIG. 12 is a graph showing a relationship between the numbers of cubic layers and variation ranges of a diameter of a well layer.

FIG. 13 is a graph showing a relationship between the numbers of cubic layers and occupancy ratios of the well layer.

FIG. 14 is a graph showing a relationship between the diameters of the well layer of the column portion and optical confinement factors of the well layer.

### DESCRIPTION OF EXEMPLARY EMBODIMENTS

Hereinafter, preferred exemplary embodiments of the present disclosure will be described in detail using the figures. Note that the exemplary embodiment described hereinafter is not intended to unjustly limit the content of the present disclosure as set forth in the claims. In addition, all of the configurations described below are not necessarily essential constituent requirements of the present disclosure.

### 1. Light-Emitting Device

### 1.1. Overall Configuration

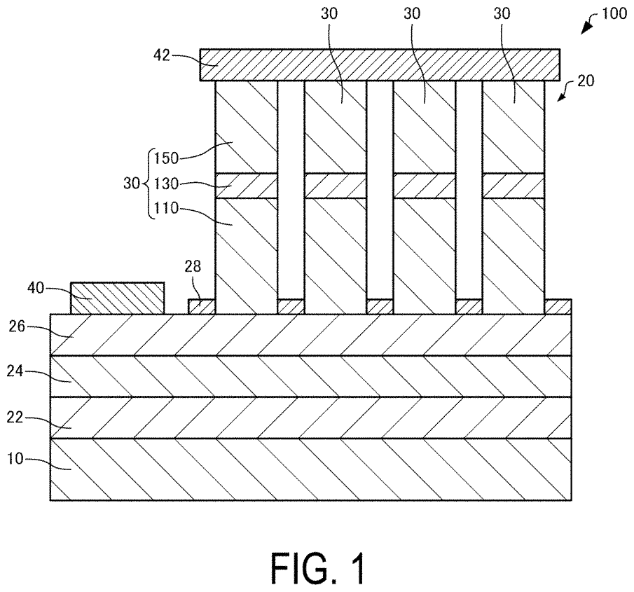

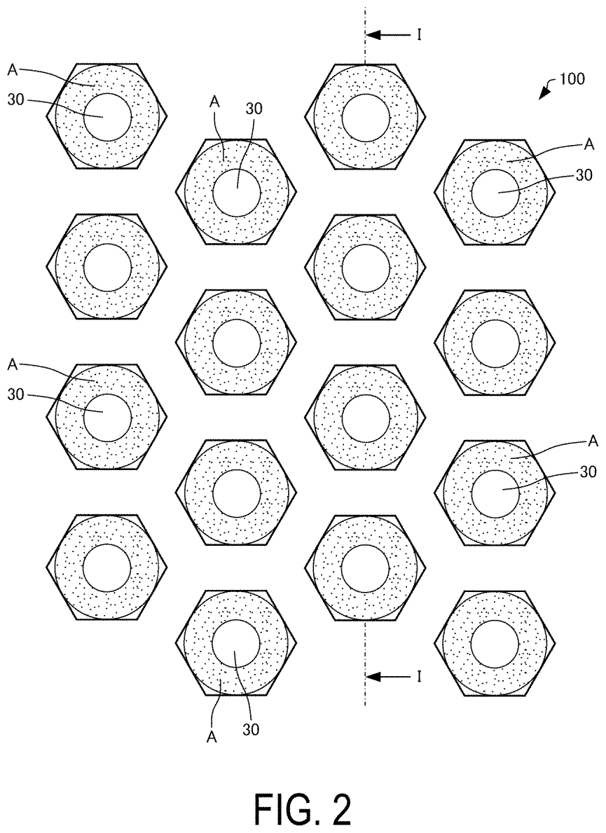

First, a light-emitting device according to the present exemplary embodiment will be described with reference to the accompanying figures. FIG. 1 is a cross-sectional view schematically illustrating a light-emitting device 100 according to the present exemplary embodiment. FIG. 2 is a plan view schematically illustrating the light-emitting device 100 according to the present exemplary embodiment. Note that, FIG. 1 is a cross-sectional view taken along a line I-I in FIG. 2.

As illustrated in FIG. 1, the light-emitting device 100 includes, for example, a substrate 10, a stacked body 20, a first electrode 40, and a second electrode 42. The light-emitting device 100 is, for example, a semiconductor laser.

The substrate 10 is, for example, a Si substrate, a GaN substrate, a sapphire substrate, a SiC substrate, or the like.

The stacked body 20 is provided at the substrate 10. In the illustrated example, the stacked body 20 is provided above the substrate 10. The stacked body 20 includes, for example, a first buffer layer 22, a DBR (Distributed Bragg Reflector) layer 24, a second buffer layer 26, a mask layer 28, and at least one column portion 30. Note that, in FIG. 2, for convenience, members other than the column portion 30 are not illustrated.

In the present specification, when a light-emitting layer 130 of the column portion 30 is referenced in a stacking direction of the stacked body 20 (hereinafter, also referred to simply as the “stacking direction”), a direction heading for a second semiconductor layer 150 of the column portion 30 from the light-emitting layer 130 is referred to as “above”, and a direction heading for the first semiconductor layer 110 of the column portion 30 from the light-emitting layer 130 is referred to as “below”. Further, a direction orthogonal to the stacking direction is referred to as an “in-plane direction”. Additionally, “the stacking direction of the stacked body 20” refers to a direction in which the first semiconductor layer 110 and the light-emitting layer 130 are stacked.

The first buffer layer 22 is provided above the substrate 10. The first buffer layer 22 is, for example, an n-type GaN layer or an AlN layer doped with Si. A lattice constant difference between the first buffer layer 22 and the DBR layer 24 is less than a difference between the substrate 10 and the DBR layer 24.

The DBR layer 24 is provided above the first buffer layer 22. The DBR layer 24 includes, for example, a multilayer film of an AlInN layer and a GaN layer, a multilayer film of an AlGaN layer and a GaN layer, or a multilayer film of an AlN layer and a GaN layer. The DBR layer 24 can reflect light, generated in the light-emitting layer 130 and heading for the substrate 10 side, toward the second electrode 42 side.

The second buffer layer 26 is provided above the DBR layer 24. The second buffer layer 26 is, for example, an n-type GaN layer doped with Si. A thickness of the second buffer layer 26 is, for example, from 50 nm to 1000 nm.

The mask layer 28 is provided above the second buffer layer 26. The mask layer 28 is, for example, a titanium layer, a titanium oxide layer, a silicon layer, a silicon oxide layer, or the like. The mask layer 28 functions as a mask for growing the column portion 30.

The column portion 30 is provided above the second buffer layer 26. The column portion 30 has a columnar shape protruding upward from the second buffer layer 26. In other words, the column portion 30 protrudes upward from the substrate 10 via the second buffer layer 26, the DBR layer 24, and the first buffer layer 22. The column portion 30 is also referred to as, for example, a nano-column, a nano-wire, a nano-rod, or a nano-pillar. A planar shape of the column portion 30 is, for example, a polygon such as a hexagon, or a circle. In the example illustrated in FIG. 2, the planar shape of the column portion 30 is a regular hexagon.

A diameter of the column portion 30 is, for example, from 50 nm to 500 nm. By setting the diameter of the column portion 30 to be equal to or less than 500 nm, the light-emitting layer 130 of high quality crystal can be obtained, and strain present in the light-emitting layer 130 can be reduced. This makes it possible to amplify light generated in the light-emitting layer 130 with high efficiency.

Note that, “the diameter of the column portion 30” is, when the planar shape of the column portion 30 is a circle, a diameter, and when the planar shape of the column portion 30 is a shape that is not a circle, a diameter of a smallest enclosing circle. For example, the diameter of the column portion 30 is, when the planar shape of the column portion 30 is a polygon, a diameter of a smallest circle enclosing the polygon therein, and when the planar shape of the column portion 30 is an ellipse, a diameter of a smallest circle enclosing the ellipse therein. This also applies to “a diameter of a well layer” and “a diameter of a cubic layer” described below.

A plurality of the column portions 30 are provided. An interval between the adjacent column portions 30 is, for example, from 1 nm to 500 nm. The plurality of column portions 30 are arrayed at predetermined pitches in a predetermined direction as viewed in the stacking direction. The plurality of column portions 30 are arrayed in a triangular lattice shape, or a square lattice shape, for example. In the example illustrated in FIG. 2, the plurality of column portions 30 are arrayed in a regular triangular lattice shape. The plurality of column portions 30 form a photonic crystal, and can express an effect of the photonic crystal. Although not illustrated, the number of column portions 30 provided may be only one.

Note that, “the pitch of the column portions 30” is a distance between centers of the respective adjacent column portions 30 in a predetermined direction. “The center of the column portion 30” refers to, when the planar shape of the column portion 30 is a circle, a center of the circle, and when the planar shape of the column portion 30 is a shape other than a circle, a center of a smallest enclosing circle. For example, the center of the column portion 30 is, when the planar shape of the column portion 30 is a polygon, a center of a smallest circle enclosing the polygon therein, and when the planar shape of the column portion 30 is an ellipse, a center of a smallest circle enclosing the ellipse therein.

As illustrated in FIG. 1, the column portion 30 includes the first semiconductor layer 110, the light-emitting layer 130, and the second semiconductor layer 150. Note that, for convenience, the column portion 30 is illustrated in a simplified manner in FIG. 1. A detailed configuration of the column portion 30 will be described later.

The first semiconductor layer 110 is provided above the DBR layer 24. The first semiconductor layer 110 is provided between the substrate 10 and the light-emitting layer 130. The first semiconductor layer 110 is a semiconductor layer of a first conductivity type. The first semiconductor layer 110 is, for example, an n-type GaN layer doped with Si.

The light-emitting layer 130 is provided between the first semiconductor layer 110 and the second semiconductor layer 150. The light-emitting layer 130 generates light by being injected with a current. The light-emitting layer 130 includes a well layer and a barrier layer not illustrated in FIG. 1. The well layer and barrier layer are each an i-type semiconductor layer where impurities are not intentionally doped. The well layer is, for example, an InGaN layer. The barrier layer is, for example, a GaN layer. The light-emitting layer 130 has a MQW (Multiple Quantum Well) structure constituted from the well layer and the barrier layer.

Note that, the number of well layers constituting the light-emitting layer 130 is not particularly limited. For example, the number of well layers provided may be only one, and in this case, the light-emitting layer 130 has a SQW (Single Quantum Well) structure.

The second semiconductor layer 150 is provided between the light-emitting layer 130 and the second electrode 42. The second semiconductor layer 150 is a semiconductor layer of a second conductivity type different from the first conductivity type. The second semiconductor layer 150 is, for example, a p-type GaN layer doped with Mg. The first semiconductor layer 110 and the second semiconductor layer 150 are cladding layers having a function of confining light to the light-emitting layer 130.

In the light-emitting device 100, a pin diode is constituted by the p-type second semiconductor layer 150, the i-type light-emitting layer 130, and the n-type first semiconductor layer 110. In the light-emitting device 100, when a forward bias voltage of the pin diode is applied between the first electrode 40 and the second electrode 42, a current is injected into the light-emitting layer 130, and a recombination between electrons and positive holes occurs in the light-emitting layer 130. This recombination emits light. The light generated in the light-emitting layer 130 propagates in the in-plane direction, forms a standing wave due to the effect of the photonic crystal by the plurality of column portions 30, receives a gain in the light-emitting layer 130, and laser-oscillates. Then, the light-emitting device 100 emits +1st order diffracted light and −1st order diffracted light as laser light in the stacking direction.

The first electrode 40 is provided above the second buffer layer 26. The second buffer layer 26 may be in ohmic contact with the first electrode 40. The first electrode 40 is electrically coupled to the first semiconductor layer 110. In the illustrated example, the first electrode 40 is electrically coupled to the first semiconductor layer 110 via the second buffer layer 26. As the first electrode 40, for example, a metal electrode in which a Cr layer, a Ni layers, and an Au layer are stacked in order from the second buffer layer 26 side or the like is used. The first electrode 40 is one electrode for injecting a current into the light-emitting layer 130.

The second electrode 42 is provided above the second semiconductor layer 150. The second semiconductor layer 150 may be in ohmic contact with the second electrode 42. As the second electrode 42, for example, a transparent electrode made of ITO (Indium Tin Oxide) or ZnO, a metal electrode in which a Ni layer and an Au layer are stacked in order from the second semiconductor layer 150 side, a metal electrode having a transparent electrode stacked thereon, or the like, is used. For example, by providing a metal electrode between the second semiconductor layer 150 and a transparent electrode, contact resistance of the second electrode 42 can be reduced. In this case, a thickness of the metal electrode is less than a thickness of the transparent electrode. The second electrode 42 is another electrode for injecting a current into the light-emitting layer 130.

Note that, the light-emitting device 100 is not limited to the laser, and may be an LED (Light Emitting Diode).

### 1.2. Configuration of Column Portion

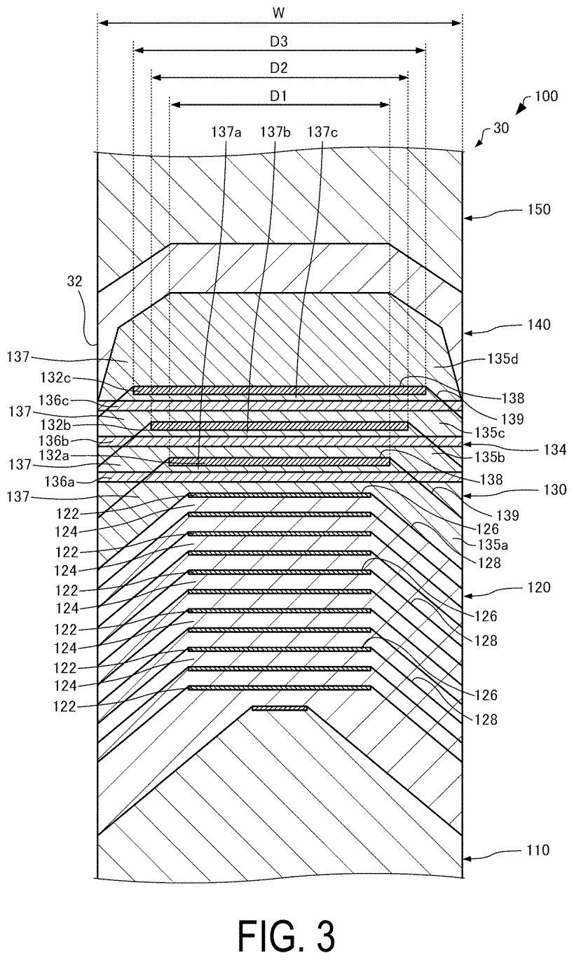

FIG. 3 is a cross-sectional view schematically illustrating the column portion 30. As illustrated in FIG. 3, the column portion 30 includes, for example, the first semiconductor layer 110, an OCL (Optical Confinement Layer) 120, the light-emitting layer 130, an EBL (Electron Blocking Layer) 140, and the second semiconductor layer 150. The first semiconductor layer 110, the OCL 120, the light-emitting layer 130, the EBL 140, and the second semiconductor layer 150 are Group III nitride semiconductors, and have a Wurzite type crystal structure, for example.

The first semiconductor layer 110 is provided between the DBR layer 24 and the OCL 120. The first semiconductor layer 110 has, for example, a hexagonal crystal structure. A size in the stacking direction of the first semiconductor layer 110 is, for example, equal to or greater than 100 nm. When the size in the stacking direction of the first semiconductor layer 110 is equal to or greater than 100 nm, a penetration defect from the substrate 10 can be reduced. Note that, although not illustrated, the first semiconductor layer 110 may include an AlGaN layer in contact with the OCL 120.

The OCL 120 is provided above the first semiconductor layer 110. The OCL 120 is provided between the first semiconductor layer 110 and the light-emitting layer 130. The OCL 120 can confine light generated in the light-emitting layer 130 to the light-emitting layer 130.

The OCL 120 has a superlattice (SL) structure in which high refractive index layers 122 and low refractive index layers 124 are alternately stacked. The high refractive index layer 122 is, for example, an i-type InGaN layer. When the high refractive index layer 122 and well layers 132a, 132b, and 132c of the light-emitting layer 130 are InGaN layers, an In composition of the high refractive index layer 122 is less than an In composition of each of the well layers 132a, 132b, and 132c. A refractive index of the high refractive index layer 122 is higher than a refractive index of the low refractive index layer 124, and is lower than a refractive index of each of the well layers 132a, 132b, 132c. The high refractive index layer 122 is spaced apart from a side surface 32 of the column portion 30. The side surface 32 is, for example, an m-plane. The low refractive index layer 124 is, for example, an i-type GaN layer. The low refractive index layer 124 has, for example, a hexagonal crystal structure. The low refractive index layer 124 constitutes the side surface 32 of the column portion 30. Note that, the high refractive index layer 122 may be n-type. The low refractive index layer 124 may be n-type.

The OCL 120 includes a c-plane 126, and a facet plane 128. The c-plane 126 is, for example, parallel to an upper surface of the substrate 10. The facet plane 128 is inclined with respect to the c-plane 126. The facet plane 128 surrounds the c-plane 126 as viewed in the stacking direction. The high refractive index layer 122 constitutes the c-plane 126. The low refractive index layer 124 constitutes the facet plane 128. A size in the stacking direction of the OCL 120 is, for example, from 10 nm to 300 nm.

The light-emitting layer 130 is provided above the OCL 120. The light-emitting layer 130 is provided between the OCL 120 and the EBL 140. The light-emitting layer 130 includes, for example, the first well layer 132a, the second well layer 132b, the third well layer 132c, and a barrier layer 134. Note that, the number of well layers included in the light-emitting layer 130 is not particularly limited.

The first well layer 132a, the second well layer 132b, and the third well layer 132c are each an i-type InGaN layers, for example. The first well layer 132a is provided between the first semiconductor layer 110 and the second well layer 132b. The second well layer 132b is provided between the first well layer 132a and the third well layer 132c. The third well layer 132c is provided between the second well layer 132b and the EBL 140.

A diameter D1 of the first well layer 132a is greater than that of the high refractive index layer 122 of the OCL 120. A diameter D2 of the second well layer 132b is greater than the diameter D1 of the first well layer 132a. A diameter D3 of the third well layer 132c is greater than the diameter D2 of the second well layer 132b. The well layers 132a, 132b, and 132c are spaced apart from the side surface 32 of the column portion 30. A thickness of each of the well layers 132a, 132b, and 132c is greater than a thickness of the high refractive index layer 122 of the OCL 120, for example.

The barrier layer 134 surrounds the well layers 132a, 132b, and 132c. The well layers 132a, 132b, and 132c are sandwiched by the barrier layer 134. The barrier layer 134 is, for example, an i-type GaN layer. The barrier layer 134 constitutes the side surface 32 of the column portion 30.

The barrier layer 134 is constituted by, for example, a first low refractive index layer 135a, a second low refractive index layer 135b, a third low refractive index layer 135c, and a fourth low refractive index layer 135d. The first low refractive index layer 135a is provided between the OCL 120 and the second low refractive index layer 135b. The second low refractive index layer 135b is provided between the first low refractive index layer 135a and the third low refractive index layer 135c. The third low refractive index layer 135c is provided between the second low refractive index layer 135b and the fourth low refractive index layer 135d. The fourth low refractive index layer 135d is provided between the third low refractive index layer 135c and the EBL 140. A refractive index of each of the low refractive index layers 135a, 135b, 135c, and 135d is lower than a refractive index of each of the well layers 132a, 132b, and 132c.

The barrier layer 134 includes, for example, a first cubic layer 136a, a second cubic layer 136b, a third cubic layer 136c, and a hexagonal layer 137. Each of the cubic layers 136a, 136b, and 136c has a cubic crystal structure. The hexagonal layer 137 has a hexagonal crystal structure. The number of cubic layers included in the barrier layer 134 is, for example, the same as the number of well layers.

The first cubic layer 136a is provided between the first semiconductor layer 110 and the first well layer 132a. The first well layer 132a is provided between the first cubic layer 136a and the second well layer 132b. The second cubic layer 136b is provided between the first well layer 132a and the second well layer 132b. The third cubic layer 136c is provided between the second well layer 132b and the third well layer 132c.

A diameter W of the first cubic layer 136a is greater than each of the diameters D1, D2, and D3 of the respective well layers 132a, 132b, and 132c. In the illustrated example, the diameter W of the first cubic layer 136a is the same as the diameter of the column portion 30. Diameters of the respective cubic layers 136a, 136b, and 136c are, for example, equal to each other. The cubic layers 136a, 136b, and 136c constitute the side surface 32 of the column portion 30.

The hexagonal layer 137 constitutes the portions other than the cubic layers 136a, 136b, and 136c of the barrier layer 134. The well layers 132a, 132b, and 132c contact the hexagonal layer 137, and do not contact the cubic layers 136a, 136b, 136c.

The hexagonal layer 137 includes, for example, a first spacer layer 137a, a second spacer layer 137b, and a third spacer layer 137c. The first spacer layer 137a is provided between the first cubic layer 136a and the first well layer 132a. The second spacer layer 137b is provided between the second cubic layer 136b and the second well layer 132b. The third spacer layer 137c is provided between the third cubic layer 136c and the third well layer 132c.

The light-emitting layer 130 includes a c-plane 138 and a facet plane 139. The c-plane 138 is parallel to the upper surface of the substrate 10, for example. The facet plane 139 is inclined with respect to the c-plane 138. The facet plane 139 surrounds the c-plane 138 as viewed in the stacking direction. The well layers 132a, 132b, and 132c each constitute the c-plane 138. The hexagonal layer 137 constitutes the facet plane 128.

The EBL 140 is provided above the light-emitting layer 130. The EBL 140 is provided between the light-emitting layer 130 and the second semiconductor layer 150. A size in the stacking direction of the EBL 140 is, for example, equal to or less than 20 nm. A material of the EBL 140 is, for example, an n-type AlGaN layer doped with Si. When the EBL 140 is the AlGaN layer, an Al composition of EBL 140 is, for example, from 5% to 25%. Note that, the EBL 140 may be a stacked body formed of an AlGaN layer and a GaN layer. The EBL 140 can block electrons overflowing from the light-emitting layer 130.

The second semiconductor layer 150 is provided above the EBL 140. The second semiconductor layer 150 is provided between the EBL 140 and the second electrode 42. The second semiconductor layer 150 has, for example, a hexagonal crystal structure.

### 1.3. Effects

In the light-emitting device 100, the column portion 30 includes the first semiconductor layer 110 of the first conductivity type, the second semiconductor layer 150 of the second conductivity type different from the first conductivity type, and the light-emitting layer 130 provided between the first semiconductor layer 110 and the second semiconductor layer 150. The first semiconductor layer 110 is provided between the substrate 10 and the light-emitting layer 130. The light-emitting layer 130 includes the first well layer 132a and the barrier layer 134. The barrier layer 134 includes the first cubic layer 136a as a first layer provided between the first semiconductor layer 110 and the first well layer 132a, and the first cubic layer 136a has a cubic crystal structure.

Therefore, in the light-emitting device 100, as compared to a case where the first cubic layer is not provided, In is unlikely to be selectively taken into the center of the column portion 30, and as illustrated in an experimental example described below, the diameter D1 of the first well layer 132a can be increased. This allows a current flowing between the first well layer 132a and the side surface 32 of the column portion 30 to be reduced. Thus, high luminance efficiency can be obtained.

In the light-emitting device 100, the diameter W of the first cubic layer 136a is greater than the diameter D1 of the first well layer 132a. Therefore, in the light-emitting device 100, the diameter D1 of the first well layer 132a can be more reliably increased.

In the light-emitting device 100, the barrier layer 134 includes the first spacer layer 137a as a second layer provided between the first cubic layer 136a and the first well layer 132a, and the first spacer layer 137a has a hexagonal crystal structure. Therefore, in the light-emitting device 100, strain generated in the first well layer 132a can be reduced, as compared to a case where the first spacer layer is not provided and the first cubic layer contacts the first well layer.

In the light-emitting device 100, the light-emitting layer 130 includes the second well layer 132b, and the first well layer 132a is provided between the first cubic layer 136a and the second well layer 132b, and the diameter W of the first cubic layer 136a is greater than the diameter D2 of the second well layer 132b. Therefore, in the light-emitting device 100, the diameter D2 of the second well layer 132b can be more reliably increased.

In the light-emitting device 100, the diameter D2 of the second well layer 132b is greater than the diameter D2 of the first well layer 132a. Therefore, in the light-emitting device 100, a current flowing between the second well layer 132b and the side surface 32 of the column portion 30 can be reduced, as compared to a case where the diameter D2 is equal to or less than the diameter D1.

The light-emitting device 100 includes the plurality of column portions 30, and the plurality of column portions 30 constitute the photonic crystal. Thus, in the light-emitting device 100, light generated in the light-emitting layer 130 can be emitted in the stacking direction as laser light.

Furthermore, in the light-emitting device 100, a part where the light generated in the light-emitting layer 130 and the first well layer 132a overlap can be increased. The light generated in the light-emitting layer 130 distributes such that, as illustrated in FIG. 2, as viewed in the stacking direction, intensity is high in a donut-shaped region A, and intensity is low at the center of the column portion 30, due to the photonic crystal effect of the plurality of column portions 30 arrayed periodically. Thus, by increasing the diameter D1 of the first well layer 132a, the part where the light generated in the light-emitting layer 130 and the first well layer 132a overlap can be increased. This makes it possible to improve an optical confinement factor of the first well layer 132a.

In the light-emitting device 100, the first well layer 132a is the InGaN layer, and the barrier layer 134 is the GaN layer. Therefore, in the light-emitting device 100, even when the first well layer 132a is the InGaN layer that is easily and selectively grown at the center of the column portion 30, the diameter D1 of the first well layer 132a can be increased.

### 2. Method of Manufacturing Light-Emitting Device

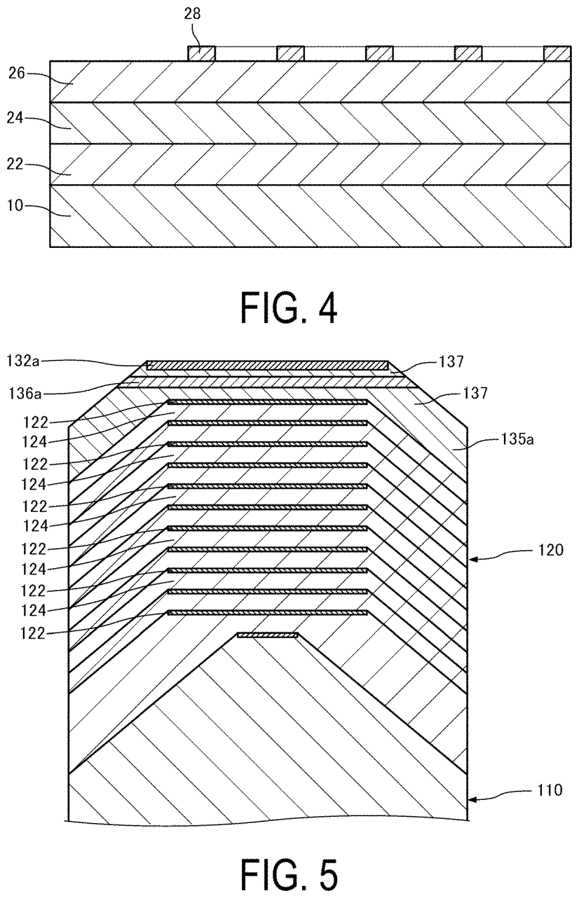

Next, a method of manufacturing light-emitting device 100 according to the present exemplary embodiment will be described with reference to the figures. FIG. 4 to FIG. 7 are cross-sectional views schematically illustrating manufacturing processes of the light-emitting device 100 according to the present exemplary embodiment.

As illustrated in FIG. 4, the first buffer layer 22, the DBR layer 24, and the second buffer layer 26 are epitaxially grown in this order above the substrate 10. Examples of the method of epitaxially growing include an MBE (Molecular Beam Epitaxy) method, an MOCVD (Metal Organic Chemical Vapor Deposition) method, and the like. The growth of the first buffer layer 22, the DBR layer 24, and the second buffer layer 26 is performed while a dopant is radiated.

Next, the mask layer 28 is formed above the DBR layer 24. The mask layer 28 is formed, for example, with an electron beam vapor deposition method or a sputtering method. Next, the mask layer 28 is patterned to form an opening portion. The patterning is performed, for example, with electron beam lithography and dry etching.

As illustrated in FIG. 5, the first semiconductor layer 110 is epitaxially grown above the DBR layer 24. The growth of the first semiconductor layer 110 is performed using the mask layer 28 as a mask. In the growth of the first semiconductor layer 110, for example, at a film formation temperature from 700° C. to 1000° C., in a case of the MBE method, a Ga atom is supplied and an N atom is supplied using RF (Radio Frequency) plasma or using NH₃ as a gas source, and in a case of the MOCVD method, TMG (trimethylgallium) is supplied via a carrier gas of N₂ or H₂, and an N atom is supplied using an NH₃ gas. A supply direction of the Ga atom and the N atom is not particularly limited, simultaneous supply may be performed, alternate supply may be performed, simultaneous supply may be performed after alternate supply, or alternate supply may be performed after simultaneous supply. The growth of the first semiconductor layer 110 is performed while a dopant is radiated.

Next, The OCL 120 is epitaxially grown above the first semiconductor layer 110. When the OCL 120 constituted by the high refractive index layer 122, which is the InGaN layer, and the low refractive index layer 124, which is the GaN layer, is grown, and the high refractive index layer 122 is grown, a flow ratio of In to Ga is set to, for example, from 40% to 60%, and may be set to 50%. When the low refractive index layer 124 is grown, the flow ratio of In to Ga is set to, for example, from 5% to 20%, and may be set to 10%. Note that, the flow ratio of Ga and In is adjusted as appropriate in accordance with a wavelength of light generated in the light-emitting layer 130.

Next, the first low refractive index layer 135a and the first well layer 132a are epitaxially grown in this order above the OCL 120. The first low refractive index layer 135a is constituted by the first cubic layer 136a and the hexagonal layer 137. When the first cubic layer 136a and the hexagonal layer 137 that are GaN layers are grown, a supply amount of Ga is increased when the first cubic layer 136a is grown, as compared to the growth of the hexagonal layer 137. Accordingly, the crystal structure of the first cubic layer 136a can be made to be cubic. When the first low refractive index layer 135a and the first well layer 132a are grown with the MBE method, the supply amount of Ga is controlled by adjusting a shutter or a cell flow rate. When the first low refractive index layer 135a and the first well layer 132a are grown with the MOCVD method, the supply amount of Ga is controlled by adjusting a switching supply amount of a Ga line.

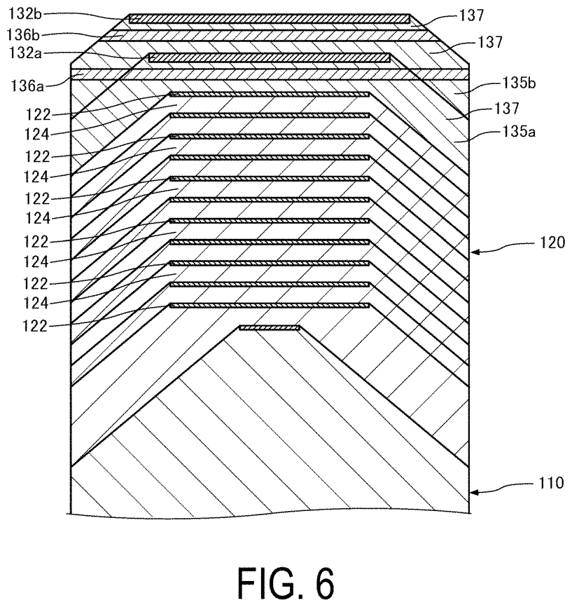

As illustrated in FIG. 6, the second low refractive index layer 135b and the second well layer 132b are epitaxially grown in this order above the first well layer 132a and above the first low refractive index layer 135a. When the second low refractive index layer 135b is grown, the first cubic layer 136a grows in a lateral direction. The “lateral direction” is the in-plane direction. The second low refractive index layer 135b is constituted by the cubic layers 136a, 136b, and the hexagonal layer 137.

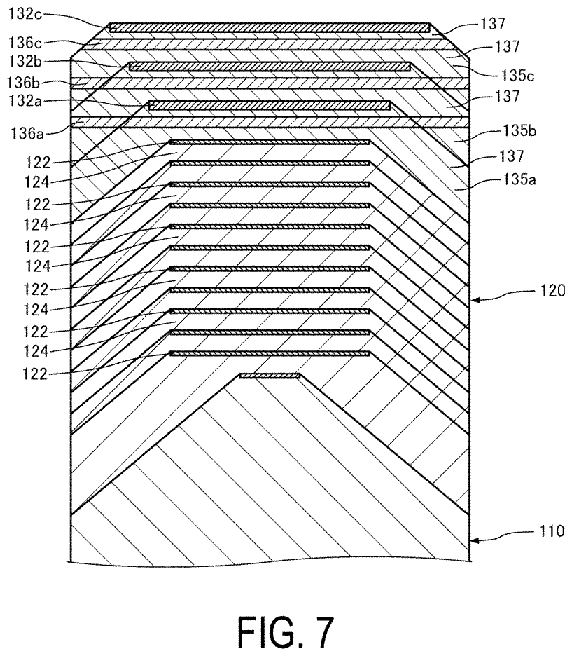

As illustrated in FIG. 7, the third low refractive index layer 135c and the third well layer 132c are epitaxially grown in this order above the second well layer 132b and above the second low refractive index layer 135b. When the third low refractive index layer 135c is grown, the second cubic layer 136b grows in the lateral direction. The third low refractive index layer 135c is constituted by the cubic layers 136b, 136c and the hexagonal layer 137.

As illustrated in FIG. 3, the fourth low refractive index layer 135d is epitaxially grown above the third well layer 132c and above the third low refractive index layer 135c. In the growth of the fourth low refractive index layer 135d, the third cubic layer 136c grows in the lateral direction. The fourth low refractive index layer 135d is constituted by the third cubic layer 136c and the hexagonal layer 137. The light-emitting layer 130 can be formed with the above processes.

Next, the EBL 140 and the second semiconductor layer 150 are epitaxially grown in this order above the light-emitting layer 130. In the growth of the EBL 140 and the second semiconductor layer 150, for example, at a film formation temperature from 700° C. to 1000° C., in a case of the MBE method, Al and Ga atoms are supplied and an N atom is supplied using RF plasma or using NH₃ as a gas source, and in a case of the MOCVD method, TMA (trimethylamine) and TMG are supplied via a carrier gas of N₂ or H₂, and an N atom is supplied using an NH₃ gas. A supply direction of the Ga atom and the N atom is not particularly limited, simultaneous supply may be performed, alternate supply may be performed, simultaneous supply may be performed after alternate supply, or alternate supply may be performed after simultaneous supply. The growth of the EBL 140 and the second semiconductor layer 150 is performed while a dopant is radiated. The plurality of column portions 30 can be formed with the above processes.

As illustrated in FIG. 1, the second electrode 42 is formed above the second semiconductor layer 150. Next, the first electrode 40 is formed above the DBR layer 24. The first electrode 40 and the second electrode 42 are formed with, for example, the sputtering method, a vacuum vapor deposition method, and the like. Note that, the order of the process of forming the first electrode 40 and the process of forming the second electrode 42 is not particularly limited.

According to the above processes, the light-emitting device 100 can be manufactured.

### 3. Projector

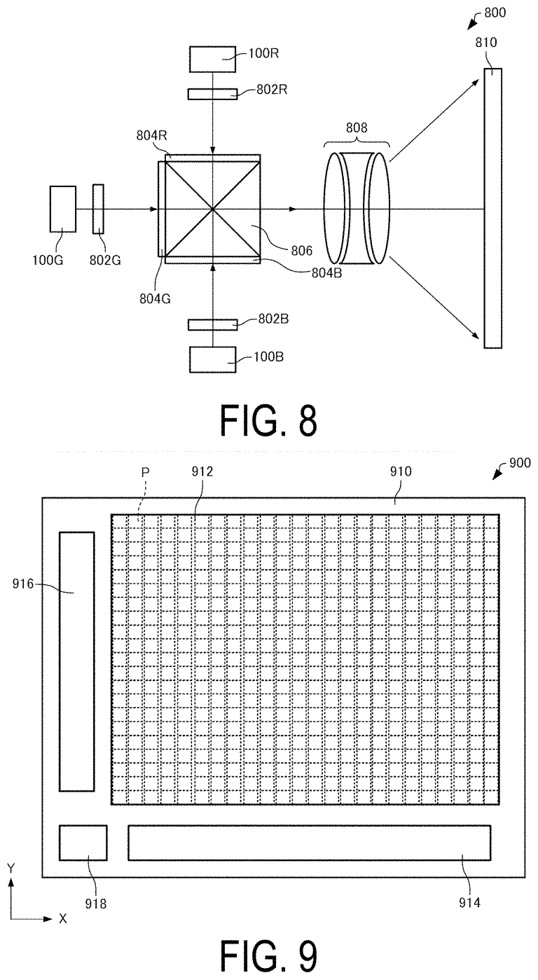

Next, a projector according to the present exemplary embodiment will be described with reference to the accompanying figures. FIG. 8 is a diagram schematically illustrating a projector 800 according to the present exemplary embodiment.

The projector 800 includes, for example, as a light source, the light-emitting device 100.

The projector 800 includes a housing (not illustrated), and a red light source 100R, a green light source 100G, and a blue light source 100B that emit red light, green light, and blue light, respectively, included in the housing. Note that, for convenience, in FIG. 8, the red light source 100R, the green light source 100G, and the blue light source 100B are simplified.

The projector 800 further includes a first optical element 802R, a second optical element 802G, a third optical element 802B, a first light modulating device 804R, a second light modulating device 804G, a third light modulating device 804B, and a projection device 808, which are provided in the housing. The first light modulating device 804R, the second light modulating device 804G, and the third light modulating device 804B are, for example, transmission type liquid crystal light valves. The projection device 808 is, for example, a projection lens.

Light emitted from the red light source 100R is incident on the first optical element 802R. Light emitted from the red light source 100R is condensed by the first optical element 802R. Note that, the first optical element 802R may have a function other than the condensing. The same applies to the second optical element 802G and the third optical element 802B described below.

The light condensed by the first optical element 802R is incident on the first light modulating device 804R. The first light modulating device 804R modulates the incident light in accordance with image information. Then, the projection device 808 expands an image formed by the first light modulating device 804R and projects the image onto a screen 810.

Light emitted from the green light source 100G is incident on the second optical element 802G. The light emitted from the green light source 100G is condensed by the second optical element 802G.

The light condensed by second optical element 802G is incident on the second light modulating device 804G. The second light modulating device 804G modulates the incident light in accordance with the image information. Then, the projection device 808 expands an image formed by the second light modulating device 804G and projects the image onto the screen 810.

Light emitted from the blue light source 100B is incident on the third optical element 802B. The light emitted from blue light source 100B is condensed by the third optical element 802B.

The light focused by the third optical element 802B is incident on the third light modulating device 804B. The third light modulating device 804B modulates the incident light in accordance with the image information. Then, the projection device 808 expands an image formed by the third light modulating device 804B and projects the image onto the screen 810.

Also, the projector 800 can include a cross dichroic prism 806 that synthesizes light emitted from the first light modulating device 804R, light emitted from the second light modulating device 804G, and light emitted from the third light modulating device 804B, and guides the synthesized light to the projection device 808.

The three types of colored light modulated respectively by the first light modulating device 804R, the second light modulating device 804G, and the third light modulating device 804B are incident on the cross dichroic prism 806. The cross dichroic prism 806 is formed by bonding four right-angle prisms together, and a dielectric multilayer film configured to reflect the red light and a dielectric multilayer film configured to reflect the blue light are disposed at inner surfaces of the prisms. The three types of colored light are synthesized by these dielectric multilayer films to form light representing a color image. Then, the synthesized light is projected onto the screen 810 by the projection device 808, and an enlarged image is displayed.

Note that, by controlling the light-emitting device 100 as a pixel of an image in accordance with the image information, the red light source 100R, the green light source 100G, and the blue light source 100B may directly form an image without using the first light modulating device 804R, the second light modulating device 804G, and the third light modulating device 804B. Then, the projection device 808 may expand the image formed by the red light source 100R, the green light source 100G, and the blue light source 100B, and project the expanded image onto the screen 810.

In addition, in the example described above, the transmission type liquid crystal light valve is used as the light modulating device, but a light valve other than liquid crystal may be used, or a reflective type light valve may be used. Examples of such a light valve include, for example, a reflective type liquid crystal light valve and a digital micro mirror device. Also, the configuration of the projection device is changed as appropriate depending on a type of a light valve used.

Further, by causing light from a light source to scan on a screen, the light source can also be applied to a light source device of a scanning type image display device having a scanner, which is an image forming apparatus that causes an image of a desired size to be displayed on a display surface.

### 4. Display

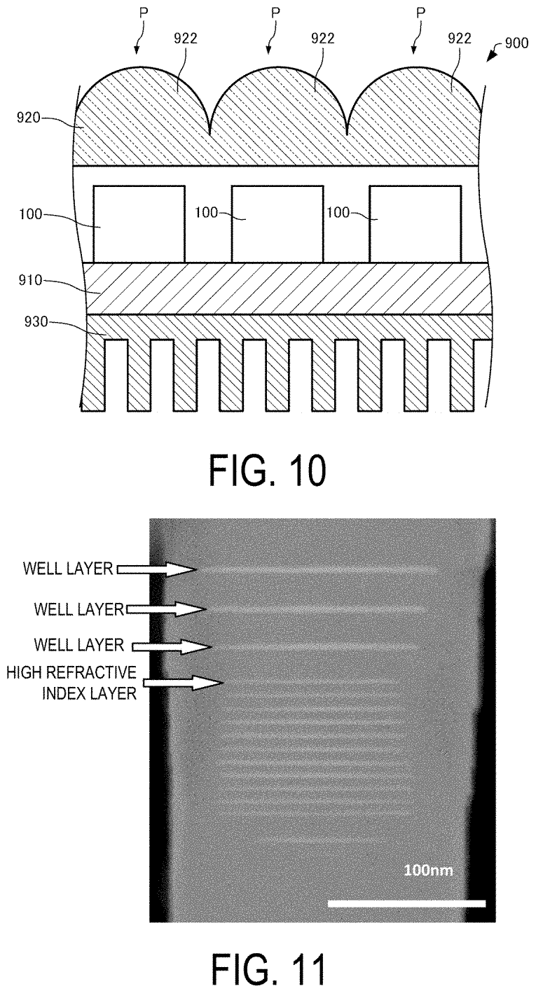

Next, a display according to the present exemplary embodiment will be described with reference to the accompanying figures. FIG. 9 is a plan view schematically illustrating a display 900 according to the present exemplary embodiment. FIG. 10 is a cross-sectional view schematically illustrating the display 900 according to the present exemplary embodiment. Note that, in FIG. 9, an X-axis and a Y-axis are illustrated, as two axes orthogonal to each other, for convenience.

The display 900 includes, for example, as a light source, the light-emitting device 100.

The display 900 is a display device that displays an image. Images include those that display only character information. The display 900 is a self-emitting type display. The display 900 includes a printed wired board 910, a lens array 920, and a heat sink 930, as illustrated in FIG. 9 and FIG. 10.

A driving circuit for driving the light-emitting device 100 is mounted at the printed wired board 910. The driving circuit is a circuit including, for example, a CMOS (Complementary Metal Oxide Semiconductor), and the like. The driving circuit drives the light-emitting device 100 based on input image information, for example. Although not illustrated, a transmissive substrate for protecting the printed wired board 910 is disposed above the printed wired board 910.

The printed wired board 910 includes a display region 912, a data line driving circuit 914, a scanning line driving circuit 916, and a control circuit 918.

The display region 912 includes a plurality of pixels P. The pixels P are arrayed along the X-axis and the Y-axis in the illustrated example.

Although not illustrated, a plurality of scanning lines and a plurality of data lines are provided at the printed wired board 910. For example, the scanning line extends along the X-axis, the data line extends along the Y-axis. The scanning line is coupled to the scanning line driving circuit 916. The data line is coupled to the data line driving circuit 914. The pixel P is provided corresponding to an intersection of the scanning line and the data line.

One pixel P includes, for example, one light-emitting device 100, one lens 922, and a pixel circuit (not illustrated). The pixel circuit includes a switching transistor that functions as a switch of the pixel P, a gate of the switching transistor is coupled to the scanning line, and one of a source and a drain is coupled to the data line.

The data line driving circuit 914 and the scanning line driving circuit 916 are circuits that control drive of the light-emitting device 100 constituting the pixel P. The control circuit 918 controls display of an image.

Image data is supplied to the control circuit 918 from an upper circuit. The control circuit 918 supplies various signals based on the image data to the data line driving circuit 914 and the scanning line driving circuit 916.

When the scanning line is selected by activating a scanning signal by the scanning line driving circuit 916, the switching transistor of the selected pixel P is on. At this time, the data line driving circuit 914 supplies a data signal from the data line to the selected pixel P, and thus the light-emitting device 100 of the selected pixel P emits light according to the data signal.

The lens array 920 includes a plurality of lenses 922. One lens 922 is provided, for example, for one light-emitting device 100. Light emitted from the light-emitting device 100 is incident on one lens 922.

The heat sink 930 contacts the printed wired board 910. A material of heat sink 930 is, for example, metal such as copper or aluminum. The heat sink 930 releases heat generated in the light-emitting device 100.

The light-emitting device according to the exemplary embodiment described above can be used for applications other than the projector and the display. Examples of the applications other than the projector and the display include, for example, an indoor or outdoor lighting, a laser printer, a scanner, an in-car light, a sensing device using light, and a light source for a communication device, and the like. Also, the light-emitting device according to the exemplary embodiment described above can be used as a display device for a head-mounted display.

### 5. Experimental Examples

### 5.1. TEM Observation

A column portion corresponding to the column portion 30 of the light-emitting device 100 illustrated in FIG. 2 was manufactured. The column portion includes a first semiconductor layer, an OCL, a light-emitting layer, an EBL, and a second semiconductor layer. The first semiconductor layer, the OCL, the light-emitting layer, the EBL, and the second semiconductor layer were epitaxially grown by an MBE method. The first semiconductor layer was an n-type GaN layer. A high refractive index layer of the OCL was an i-type InGaN layer, and a low refractive index layer was an i-type GaN layer. A well layer of the light-emitting layer was an i-type InGaN layer, and a barrier layer was an i-type GaN layer. The three well layers were formed. A supply amount of Ga was adjusted when the barrier layer was grown, and the barrier layer having three cubic layers was formed. The manufactured column portion was observed with a TEM (Transmission Electron Microscope).

FIG. 11 illustrates a TEM image. Specifically, FIG. 11 illustrates an HAADF-STEM (High-Angle Annular Dark Field Scanning TEM) image of the column portion. As illustrated in FIG. 11, a diameter of the well layer was found to be greater than a diameter of the high refractive index layer of the OCL. In the three well layers, a well layer formed on an upper side was found to have a greater diameter.

### 5.2. Simulation for Relationship Between the Number of Cubic Layers and Diameter of Well Layer

A model of a light-emitting layer of the column portion was manufactured, and in the model, a simulation for a relationship between the number of cubic layers and the diameter of the well layer was performed. In the simulation, a plane wave expansion method was used. The well layer was an i-type InGaN layer, and an i-type barrier layer was a GaN layer. The number of cubic layers of the barrier layer was changed.

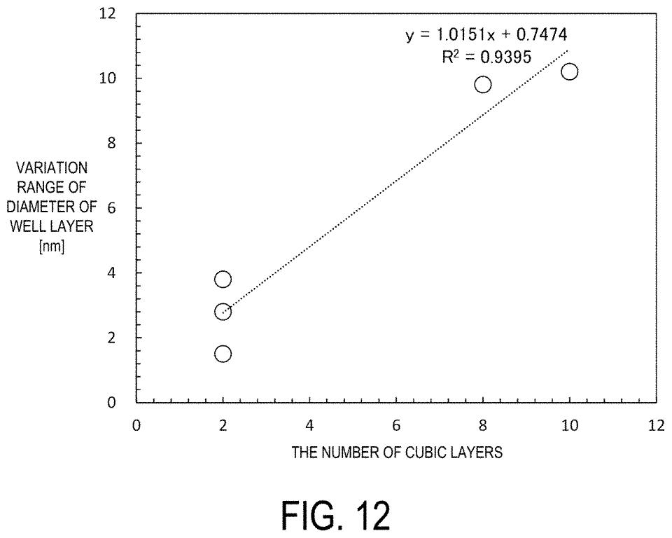

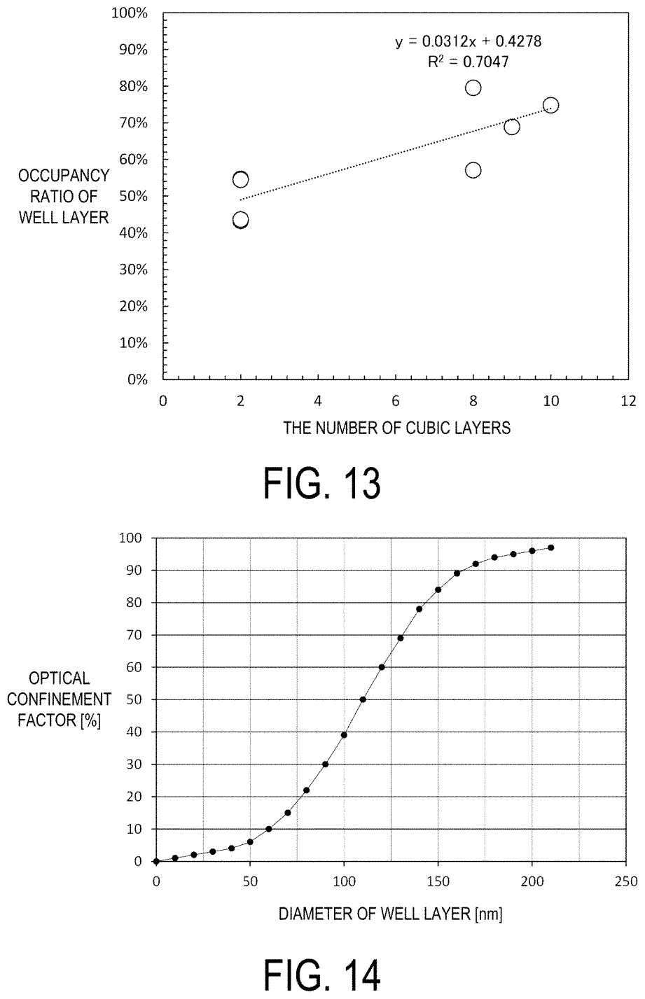

FIG. 12 is a graph showing a relationship between the numbers of cubic layers and variation ranges of the diameter of the well layer. The “variation range of the diameter of the well layer” is a variation range from the diameter of the well layer, when the cubic layer is not provided, that is, when the number of the cubic layers is zero. FIG. 13 is a graph showing a relationship between the numbers of cubic layers and occupancy ratios of the well layer. The “occupancy ratio of the well layer” is a ratio of the diameter of the well layer to a diameter of the column portion.

As illustrated in FIG. 12 and FIG. 13, it was found that the diameter of the well layer can be increased by providing the cubic layer. Furthermore, it was found that by increasing the number of cubic layers, the diameter of the well layer increased.

FIG. 14 is a graph showing a relationship between the diameter of the well layer of the column portion and optical confinement factor of the well layer. The number of cubic layers of the barrier layer was one. A period of the column portion was 210 nm. An emission wavelength was 450 nm. An oscillation mode of light generated in the well layer was set to a TE mode. The optical confinement factor is an optical confinement factor in the in-plane direction. As illustrated in FIG. 14, it was found that more than 50% of light can be confined with the diameter of the well layer of 110 nm, and more than 80% of light can be confined with the diameter of the well layer of 150 nm.

The exemplary embodiments and modified examples described above are merely examples and the present disclosure is not limited thereto. For example, each exemplary embodiment and each modified example can be combined as appropriate.

The present disclosure includes configurations that are substantially identical to the configurations described in the exemplary embodiments, for example, a configuration having the same functions, methods, and results, or a configuration having the same purposes and effects. Furthermore, the present disclosure includes a configuration obtained by replacing non-essential parts of the configurations described in the exemplary embodiments. Additionally, the present disclosure includes a configuration that achieves the same effects as those of the configurations described in the exemplary embodiments, or a configuration that can achieve the same purposes as those of the configurations described in the exemplary embodiments. Further, the present disclosure includes a configuration in which a known technology is added to the configurations described in the exemplary embodiments.

The following contents are derived from the above-described exemplary embodiments and modified examples.

An aspect of a light-emitting device includes

a substrate, and

at least one column portion, wherein

the column portion includes

a first semiconductor layer of a first conductivity type,

a second semiconductor layer of a second conductivity type different from the first conductivity type, and

a light-emitting layer provided between the first semiconductor layer and the second semiconductor layer,

the first semiconductor layer is provided between the substrate and the light-emitting layer,

the light-emitting layer includes a first well layer, and a barrier layer,

the barrier layer includes a first layer provided between the first semiconductor layer and the first well layer, and

the first layer has a cubic crystal structure.

According to the light-emitting device, a diameter of the first well layer can be more reliably increased.

In an aspect of the light-emitting device,

a diameter of the first layer may be greater than the diameter of the first well layer.

According to the light-emitting device, the diameter of the first well layer can be increased.

In an aspect of the light-emitting device,

the barrier layer may include a second layer provided between the first layer and the first well layer, and

the second layer may have a hexagonal crystal structure.

According to the light-emitting device, strain generated in the first well layer can be reduced.

In an aspect of the light-emitting device, the light-emitting layer may include a second well layer,

the first well layer may be provided between the first layer and the second well layer, and

the diameter of the first layer may be greater than a diameter of the second well layer.

According to the light-emitting device, the diameter of the second well layer can be more reliably increased.

In an aspect of the light-emitting device,

the diameter of the second well layer may be greater than the diameter of the first well layer.

According to the light-emitting device, a current flowing between the second well layer and a side surface of the column portion can be reduced.

In an aspect of the light-emitting device,

a plurality of the column portions may be included, and

the plurality of column portions may form a photonic crystal.

According to the light-emitting device, light generated in the light-emitting layer can be emitted in a stacking direction as laser light.

In an aspect of the light-emitting device,

the first well layer may be an InGaN layer, and

the barrier layer may be a GaN layer.

According to the light-emitting device, even when the first well layer is the InGaN layer that is easily and selectively grown at a center of the column portion, the diameter of the first well layer can be increased.

Ae aspect of a projector

includes an aspect of the light-emitting device.

An aspect of a display

includes an aspect of the light-emitting device.

What is claimed is:

1. A light-emitting device, comprising:
a substrate; and
a column portion, wherein
the column portion include:
a first semiconductor layer of a first conductivity type;
a second semiconductor layer of a second conductivity type that is different from the first conductivity type; and
a light-emitting layer provided between the first semiconductor layer and the second semiconductor layer,
the first semiconductor layer is provided between the substrate and the light-emitting layer,
the light-emitting layer includes a first well layer and a barrier layer,
the barrier layer includes a first layer provided between the first semiconductor layer and the first well layer, and
the first layer has a cubic crystal structure.

2. The light-emitting device according to claim 1, wherein
a diameter of the first layer is greater than a diameter of the first well layer.

3. The light-emitting device according to claim 1, wherein
the barrier layer includes a second layer provided between the first layer and the first well layer, and
the second layer has a hexagonal crystal structure.

4. The light-emitting device according to claim 1, wherein
the light-emitting layer includes a second well layer,
the first well layer is provided between the first layer and the second well layer, and
a diameter of the first layer is greater than a diameter of the second well layer.

5. The light-emitting device according to claim 4, wherein
a diameter of the second well layer is greater than a diameter of the first well layer.

6. The light-emitting device according to claim 1, comprising a plurality of the column portions, the plurality of column portions forming a photonic crystal.

7. The light-emitting device according to claim 1, wherein
the first well layer is an InGaN layer, and
the barrier layer is a GaN layer.

8. A projector comprising the light-emitting device according to claim 1.

9. A display comprising the light-emitting device according to claim 1.
